(19) United States
(12) Patent Application Publication
(10) Pub. No.: US 2013/0292378 A1
(43) Pub. Date: Nov. 7, 2013

(54) MOBILE DEVICE CASE HAVING INTEGRATED LATCH

(71) Applicant: A.G. Findings & Mfg. Co., Inc., Fort Lauderdale, FL (US)

(72) Inventor: Fernando TAGES, Coral Springs, FL (US)

(21) Appl. No.: 13/847,878

(22) Filed: Mar. 20, 2013

Related U.S. Application Data
(60) Provisional application No. 61/642,863, filed on May 4, 2012.

(51) Int. Cl. H05K 5/00

(52) U.S. Cl. CPC H05K 5/0086
USPC 220/4.02

(57) ABSTRACT

A mobile device case having an integrated latch. The mobile device case includes a first portion sized to at least partially retain a mobile device. The first portion includes side wall portions including at least one corner contiguous with the side wall portions. The at least one corner includes at least one first mating element. A second portion is matable to the first portion. The second portion includes at least one flap. Each flap includes a second mating element sized to mate with the first mating element. Each flap is disposed on an exterior portion of the at least corner when the first mating element is mated to the second mating element.

### CROSS-REFERENCE TO RELATED APPLICATION

This application is related to and claims priority to U.S. Provisional No. 61/642,863, filed May 4, 2012 entitled MOBILE DEVICE CASE LATCH, the entirety of which is incorporated herein by reference.

### STATEMENT REGARDING FEDERALLY SPONSORED RESEARCH OR DEVELOPMENT

n/a

### FIELD OF THE INVENTION

The present invention relates to protective mobile device cases, and in particular, a protective mobile device case having an integrated latch.

### BACKGROUND OF THE INVENTION

Two-piece or clam-shell protective mobile device cases provide a barrier between a mobile device case retained within the case and the ambient environment, which may protect the mobile device from external elements such as dust, debris, as well as impact forces. However, the connection point or points between the two pieces that cooperate to define the mobile device case are weak points in the construction of the case.

Accordingly, latches have been devised to attach the two pieces of a clam-shell mobile device case together. Such latches, however, are cumbersome or awkward and are often composed of rigid materials that transfer impact forces directly to the mobile device during an impact event. Repeated impact events may cause such latches to become worn overtime such that the latch may fracture or otherwise become non-operational. These latches are also often aesthetically unpleasing, add unwanted size and dimension to the case, and prove difficult to open by the consumer.

Moreover, existing latches are often separate components from the mobile device case. In particular, many latches are coupled to the mobile device case by a hinge or other connector, which if fractured, may prevent the mobile device case from closing.

### SUMMARY

The present invention advantageously provides for a mobile device case having an integrated latch. The mobile device case includes a first portion sized to at least partially retain a mobile device. The first portion has an exterior and includes a plurality of corners. At least one of the plurality of corners includes at least one first mating element disposed on the exterior. A second portion matable to the first portion is included, the second portion including at least one flap, each flap including a second mating element sized to releasably engage with a corresponding first mating element. Each flap is disposed on the exterior portion of a corresponding corner when the first mating element is engaged with the second mating element.

In another embodiment, the mobile device case includes a first portion sized to receive a mobile device. A second portion is included releaseably securable to the first portion. The first portion includes a plurality of side wall portions composed of a substantially rigid material, the plurality of side wall portions includes an exterior surface. The second portion includes at least one flap releaseably securable to at least one of the plurality of side wall portions. The at least one flap contours the exterior surface of at least one of the plurality of side wall portions when the first portion is releasably secured to the second portion.

In yet another embodiment, the mobile device case includes a first housing portion including at least one corner. The at least one corner defines an exterior surface and a protuberance extending away from the exterior surface. A second housing portion is included and is releaseably engageable to the first housing portion, the second housing portion defining a substantially planar surface and including at least one flap. Each flap has an aperture in which the aperture is sized to mate with a corresponding protuberance. The at least one flap is movable from a first position in which the at least one flap is substantially orthogonal to substantially planar surface to a second position in which the at least one flap is substantially planar to the substantially planar surface. The at least one flap is adjacent and contours the exterior surface of the corner and the second portion is releasably secured to the first portion

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 is an exploded perspective view of a mobile device case constructed in accordance with the present invention;

FIG. 2 is an inside view of the second portion of the mobile device case having a latch shown in FIG. 1;

FIG. 3 is a zoomed in side view of a flap shown in FIGS. 1 and 2;

FIG. 4A is a top view of the assembled mobile device case shown in FIG. 1;

FIG. 4B is a side cross-sectional view of showing a second mating element on the flap of FIG. 3 inserted within a first mating element across Section 4B-4B from FIG. 4A;

FIG. 4C is a zoomed in view of the second mating element on the flap inserted within a first mating element shown in FIG. 4B;

FIG. 5 is a back view of the first portion of the mobile device case shown in FIG. 1 with a flap of the second portion proximate a first mating element;

FIG. 6 is an assembled view of the mobile device case shown in FIG. 1; and

FIG. 7 is perspective view of another embodiment mobile device case constructed in accordance with the present invention.

### DETAILED DESCRIPTION OF THE INVENTION

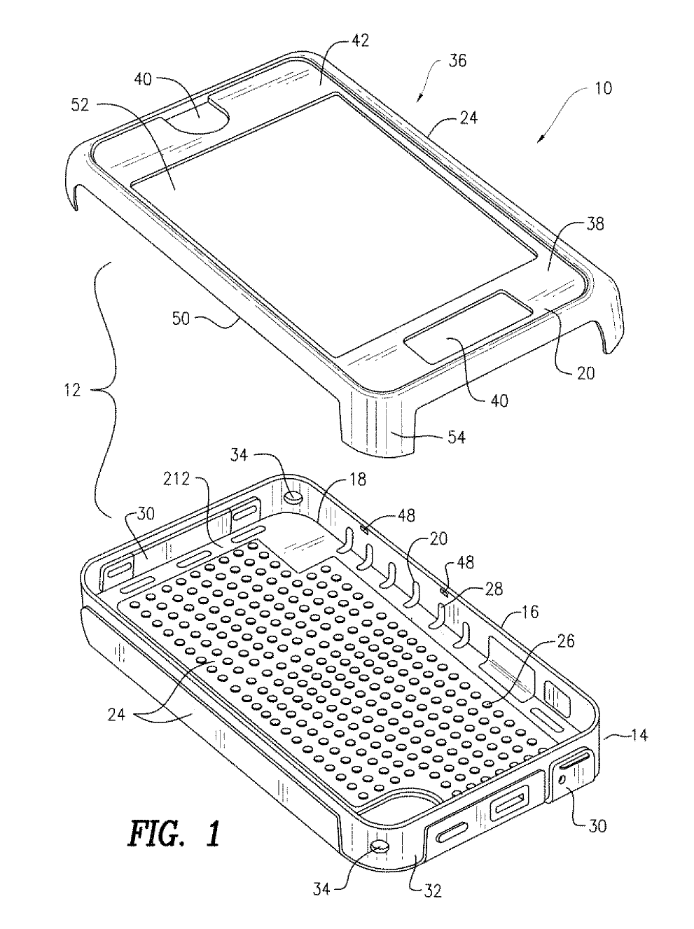

Now referring to the drawings in which like reference designators refer to like elements, there is shown in FIG. 1 a mobile device case constructed in accordance with the principles of the present invention and designated generally as “10.” The case 10 may include a housing 12 may be a multi-piece clam shell or a unitary structure sized to receive and retain a mobile device. The housing 12 may include a first portion 14 sized to receive and at least partially enclose the mobile device. For example, the dimensions of the first portion 14 may be pre-fabricated to contour a specific mobile device, for example an IPHONE, IPAD, or other mobile phone or tablet computer, and thus may vary depending on the size of the mobile device.

The first portion 14 may further include a plurality of side wall portions 16 defining a first perimeter 18 around the interior of the first portion 14. The side wall portions 16 surround the first portion 14 and may define a height substantially commensurate with a height of the mobile device housed within the first portion 14, or any height. In an exemplary embodiment, four side wall portions 16 are included on the first portion 14. The first portion 14 may include, and be at least partially composed of, a first material 20. The first material 20 may include a substantially rigid material, for example, polycarbonate (PC) or a similarly rigid material having a similar durometer hardness. The first material 20 may be included around the exterior of the side wall portions 16 and on a bottom portion 22 of the first portion 14. The first material 20 may further be contiguous around the first portion 14 such that side wall portions 16 are contiguously connected with the bottom portion 22 by the first material 20. Alternatively, the side wall portions 16 may be joined, in part, to the bottom portion 22 by other materials or may include gaps or slits along the perimeter 18 to provide for at least some flexion in the event of the an impact force being applied to the first portion 14.

Molded or affixed to the bottom portion 22 in the interior of the first portion 14 may be a second material 24. The second material 24 may be an elastomeric resilient material, for example, thermoplastic polyurethane (TPU) or other thermoplastic elastomers having a similar durometer hardness less than the durometer hardness of the first material 20. The second material 24 may span substantially the entire bottom portion 22 in the interior of the case and may further define a raised pattern of nubs 26, which may be any shape or size or pattern, that raise the mobile device a distance away from the bottom portion 22 when retained within the first portion 14. The nubs 26 may be composed of the second material 24, or other materials, and further operate to cushion and to provide friction to the mobile device when disposed within the first portion 14. In an exemplary configuration, the second material 24 is molded to the bottom portion 22 such that is spaced a distance away from the perimeter 18 and around at least a portion of the interior.

The second material 24 may further be molded or affixed onto the exterior surface of the side wall portions 16. For example, the second material 24 may extend up at least a portion of the side wall portions 16 on one or more of the side portions that comprise the side wall portions 16. In an exemplary configuration, the second material 24 may be molded on at least a substantial portion of the side wall portions 16, such that portion of the first material 20 may be exposed toward the top of the side wall portions 16 with a section of the side wall portions 16 including only the first material 20. The second material 24 may further be molded onto the side wall portion 16 to define one or more apertures allowing for sound to be emitted from the speakers through the apertures. The second material 24 may further allow for the actuation of one or more of the controls of the mobile device. For example, the second material 24 may define volume control bottoms that are operable to actuate the volume control buttons on the mobile device when pressed.

The second material 24 may further be molded into the first portion 14 such that a portion of the second material 24 joins a portion of the side wall portions 16 to the bottom portion 22 and further defines a portion of the side wall portions 16. For example, the first portion 14 may include a plurality of tension elements 28 adjoining the side wall portions 16 to the bottom portion 22. Each tension element 28 defines part of the side wall portions 16 and the bottom portion 22 and is further sized to space a mobile electronic device retained within the first portion 14 a distance away from the side wall portions 16. In particular, each tension element 28 may extend a distance from the side wall portions 16 and the bottom portion 22 toward the interior of the first portion 14. Each tension element 28 further operates as a spring to resist an impact force applied by the mobile device on the tension element 28 to cushion the mobile device when retained with the first portion 14.

The first portion 14 may further include one or more plugs 30 molded or affixed to the first portion 14. For example, the plugs 30 may be molded to a portion of the side wall portions 16 including the first material 20 and may be movable from a first position in which the plug 30 is securably inserted into an aperture defined by the first portion 14, to a second position in which the plug 30 is moved or pivoted a distance away from the first portion 14 to allow for insertion of headphones, power plugs, or other accessories. The plugs 30 may be composed of the second material 24 or other similar flexible materials.

Continuing to refer to FIG. 1, the first portion 14 further includes a plurality of corners 32. Each corner 32 may include an exposed portion of the first material 20 that defines the side wall portions 16. For example, a portion of the second material 24 spanning the side wall portions 16 on both sides of each corner 32 may taper or otherwise terminate on the corner 32 such that each corner 32 includes only the first material 20. Alternatively, one or more of the corners 32 may include a portion the second material 24 on the first portion 14. For example, the second material 24 may be included on the bottom of one or more corners 32 such that the second material 24 adjoins the portions of the second material 24 on the portion of the side wall portions 16 on both sides of each corner 32.

One or more of the corners 32 may define, or otherwise include, at least one first mating element 34. The first mating element 34 may be, for example, an aperture defined by the corner 32 in the exposed portion of the first material 20 between portions of the second material 24. For example, as shown in FIG. 1, the first mating element 34 is positioned at approximately the midpoint of the corner 32, although in other configurations, the first mating element 34 may be positioned at any position along the corner 32. The shape of the first mating element 34 may be circular, rectangular, or any shape or size. The first mating element 34 may be tapered inward such that the first mating element 34 defines a larger opening, e.g. diameter, toward the exterior of the first portion 14 compared to the opening of the corner aperture toward the interior of first portion 14. In an exemplary configuration, each corner 32 may include at least one first mating element 34 each having the same configuration, or alternatively, may be any shape or size.

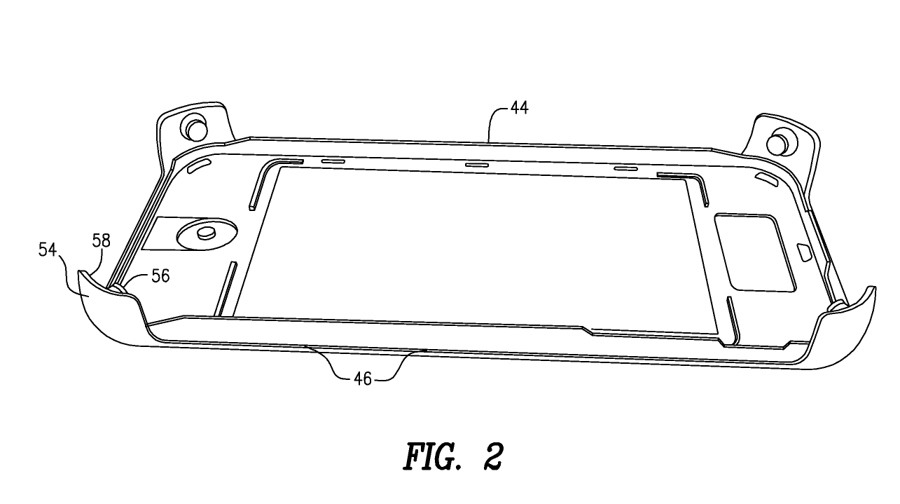

Continuing to refer to FIG. 1, the housing 12 may further including a second portion 36 releaseably securable to the first portion 14. The second portion 36 may be composed of both the first material 20 and the second material 24. For example, the second portion 36 may include the first material 20 on an upper portion 38 of the second portion 36. The upper portion 38 may further defines a plurality of upper portion apertures 40 sized to accommodate the actuation of a push-button on the mobile device or to allow an unimpeded view for an image capture device on the mobile device. The upper portion 38 may define a substantially planar surface and may further define a substantially rectangular perimeter 42 with rounded edges composed of the first material 20. The perimeter 42 may extend orthogonally a distance away from the upper portion 38 and define a lip 44 (shown in FIG. 2) insertable within a portion of the first portion 14. The lip 44 may further define a one or more recesses 46 (shown in FIG. 2) sized to receive a complementary tab 48 on the first portion 14 to releasably secure the first portion 14 to the second portion 36.

Molded to a portion of the upper portion 38 may be the second material 24 extending a distance away from the substantially rectangular perimeter 42. The second material 24 molded to the upper portion 38 may be disposed around the perimeter 42 to provide a layer of cushion to the second portion 36. The second material 24 may further define a second perimeter 50 molded to and disposed around the perimeter 42. In particular, the second perimeter 50 may be molded atop the perimeter 42 and extend a longitudinal distance away from the perimeter 42.

The second portion 36 may include a screen protector 52 which is substantially commensurate in size with a touch-screen of a mobile device retained within the first portion 14. The screen protector 52 may be transparent and flexible or substantially rigid and may further define electrical properties such that the touch-screen of the mobile device may be actuated through the screen protector 52. The screen protector 52 may further be substantially coplanar with the upper portion 38. Optionally, the second portion 36 may not include the screen protector 52.

Extending away from second perimeter 50, in a direction substantially orthogonal from screen protector 52, may be at least one flap 54. For example, four flaps 54 may be included on the second portion 36 extending from the second perimeter 50 although any number of flaps 54 may be included. The flaps 54 may be substantially commensurate in height and width as the corners 32 as to provide protection to the corners 32 during an impact event in which the housing 12 is exposed to an impact force. For example, both the corners 32 and the flaps 54 may be substantially rectangular in shape with a concave curvature. In an exemplary configuration, the flaps 54 are joined to the second perimeter 50 and form a contiguous section of the second material 24. In other embodiments, the flaps 54 may be connected to the perimeter 42 or the second perimeter 50 by a connector (not shown), such as a living hinge, discrete hinge, or other connector, that facilitates movement of the flaps 54, such that the second perimeter 50 is not contiguous with the flaps 54. The flaps 54 may further be movable from a first position in which the flaps 54 are substantially orthogonal to the screen protector 52 and biased to the first position at least a second position in which the flaps 54 are substantially coplanar with the screen protector 52. The flaps 54 may further vary in thickness compared to a thickness of the second material 24 disposed on either or both of the first portion 14 and the second portion 36. In particular, the flaps 54 may include the same or similar thickness as the thickness of the second material 24 that defines the second perimeter 50 or the second material 24 that is disposed on opposite sides of the corner 32. In other embodiments, the thickness of the flaps 54 may be greater than the thickness of the second material 24 on the first portion 14 such that it protrudes a greater distance away from the corner 32 when the first portion 14 is removeably coupled to the second portion 36 as discussed in more detail below.

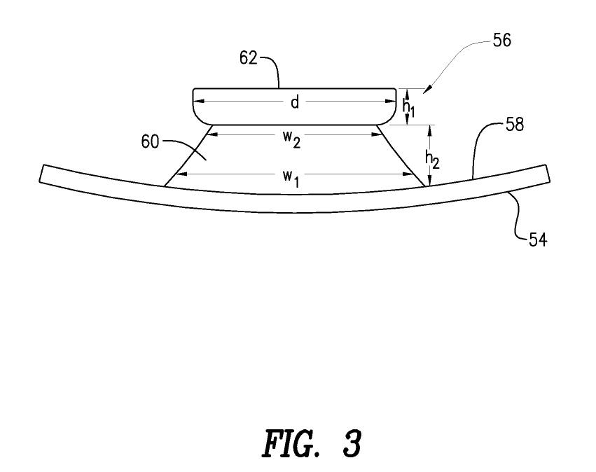

Referring now to FIGS. 2 and 3, each of the flaps 54 may include, or otherwise define, a second mating element 56 extending a distance away from an interior surface 58 of each flap 54. For example, each flap 54 may include at least one second mating element 56 positioned at substantially the center point of each flap 54. The second mating element 56 may be a nub or a protuberance composed of the same material as the flap 54, for example, the second material 24, or the second mating element 56 may be composed of a different material, for example, the first material, 20. The second mating element 56 may define a first section 60 subjacent to a second section 62. The first section 60 may be molded to the flap 54 and may taper inward as it extends from the flap 54. For example, first section 60 may be substantially frusto-conical in shape, or any shape, and may further define a width (w1) of the first section 60 proximate the interior surface 58 greater than a width (w2) of a width of the first section 60 distal the interior surface 58.

Molded or contiguous with the first section 60 is the second section 62 positioned distal the first section 60. The second section 62 may be substantially cylindrical in shape and may define a diameter (d) greater than the width (w2) of the first section 60 distal the interior surface 58 and smaller than the width (w1) of the first section 60 proximate the interior surface 58. In the configuration shown in FIG. 3, the second section 62 defines a height (h1) less than a height (h2) of the first section 60.

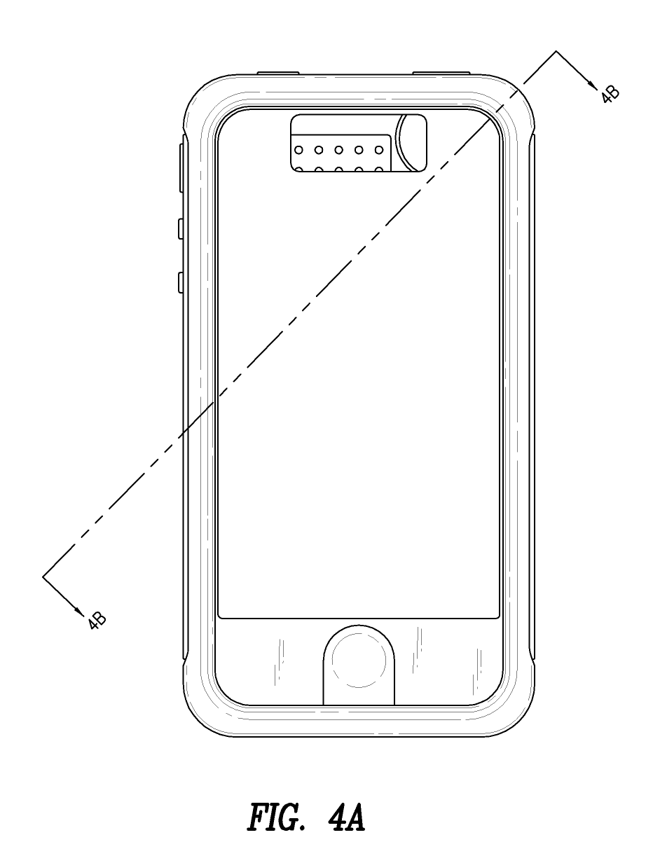

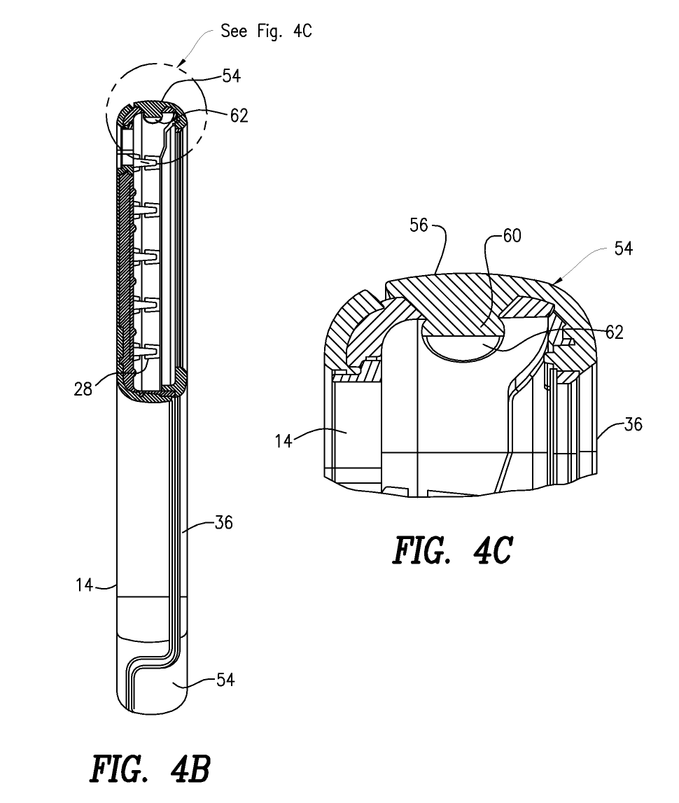

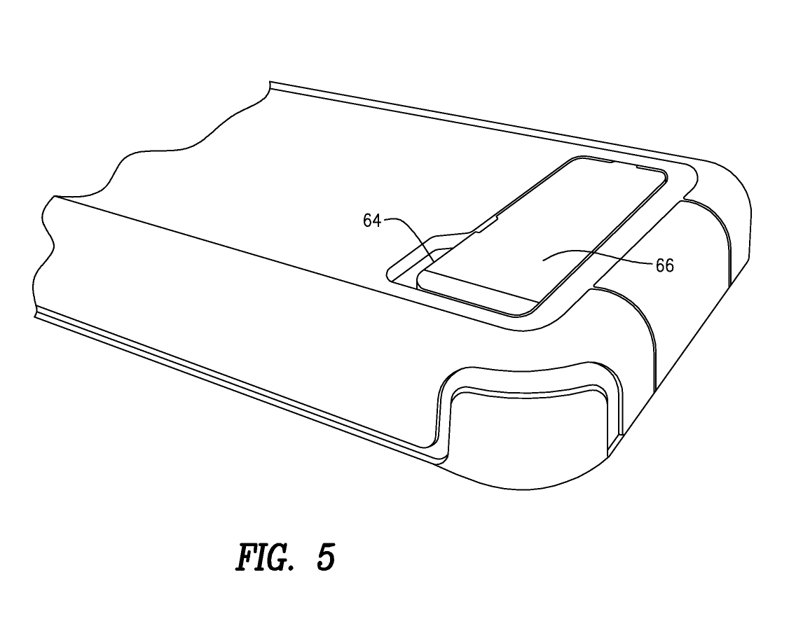

Referring now to FIGS. 4A, 4B, 4C, and 5, when the second portion 36 may engage the first portion 14, for example, by inserting the lip 44 within a portion of the first portion 14 such that tabs 48 are inserted within the recesses 46. When the tabs 48 are inserted within the recesses 46, the first portion 14 may be removeably secured to the second portion 46 with the second mating element 56 of the flaps 52 resting against the first mating element 34 such that the corner 32 is at least partially exposed. In an exemplary configuration, a pressing force applied to the second mating element 56 forces the entire second section 62 of the second mating element 56 into the first mating element 34 such that it extends into the interior of the first portion 14 and at least a portion of the first section 60 into the interior of the first portion 14. Owing to the configuration and size of the second mating element 56 with respect to the size and configuration of the first mating element 34, when the second mating element 56 is pressed within the first mating element 34, the second mating element 56 snaps into the corner 32 and the flaps 52 are pressed adjacent an exterior surface of the corners 32. In particular, the first mating element 34 tapers outward and the first section 60 of the second mating element 56 tapers inward. Additionally, the second section 62 is wider that the smallest diameter of the first mating element 34. Thus, the second section 62 is partially compressed when traversing the first mating element 34 and when the second section is disposed within the interior of the first portion 14 after passing through the first mating element 34, the flap 52 is secured against the exterior surface of the corner 32. As such, event the flaps 52 are secured to the corners 32 in a manner then prevents them from moving or shifting during an impact event.

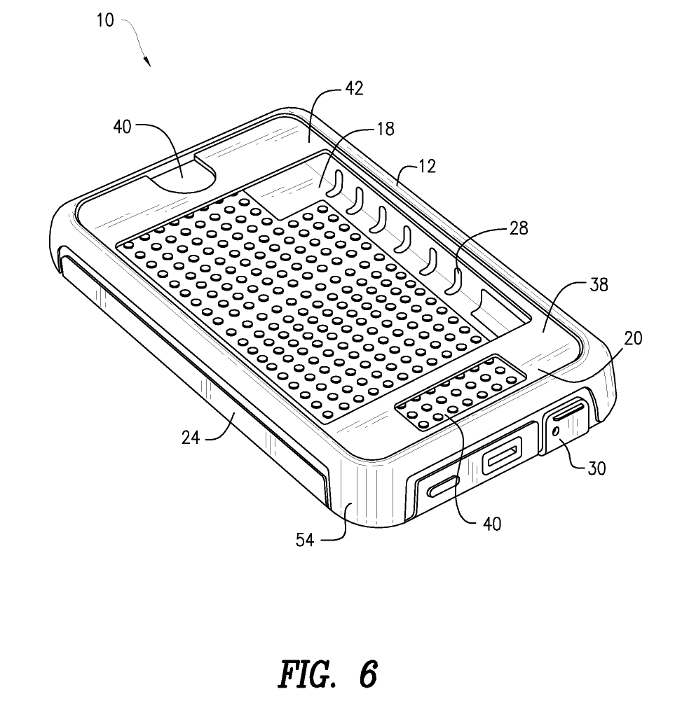

Referring now to FIGS. 5 and 6, the flaps 52 provide a resilient cushioned second layer of material 24 to the corners 32 when the second mating element 56 is inserted within the corner aperture 34. In an exemplary configuration, four flaps 52 are included on the second portion 36 and four corner apertures are included on the first portion 14. As such, each flap 52 may be pressed against each of the four corners 32 such that each corner 32 of the first portion 14 includes a flap 52. When the second mating element 56 is inserted within the corner aperture the flap 52 may be pressed against the corner 32 such that a portion of the corner 32 remains exposed. For example, a portion of the corner 32 proximate the bottom portion 22 may be exposed when the flap 52 is positioned adjacent the corner 32. In such a configuration, the user of the mobile device case 10 may release the flaps 52 from the corner 32 by pulling on a portion of the flap 52 proximate the exposed portion of the corner 32 with pulls the second mating element 56 out from the first mating element 34. When each of the four second mating elements 56 are released from their respective corner apertures 34, the first portion 14 may be detached from the second portion 36 by pulling the second portion 36 away from the first portion 14.

In other configurations, the flap 52 may not include the second mating element 56, but instead may define a substantially flat surface composed of the second material 24 to friction-fit with the corner 32 which may also be molded with, or otherwise composed of the second material 24.

As shown in FIG. 5, the exterior surface of the bottom portion 22 may include an indentation 64 sized to receive a kickstand 66 coupled to the bottom portion 22. The kickstand 66 may be movable from a first position in which it is received within the indentation and substantially co-planar with exterior surface of the bottom portion 22 to a second position in which the kickstand 66 is extend to an angle approximately 45 degrees such that the mobile device case may rest on a surface at any angle.

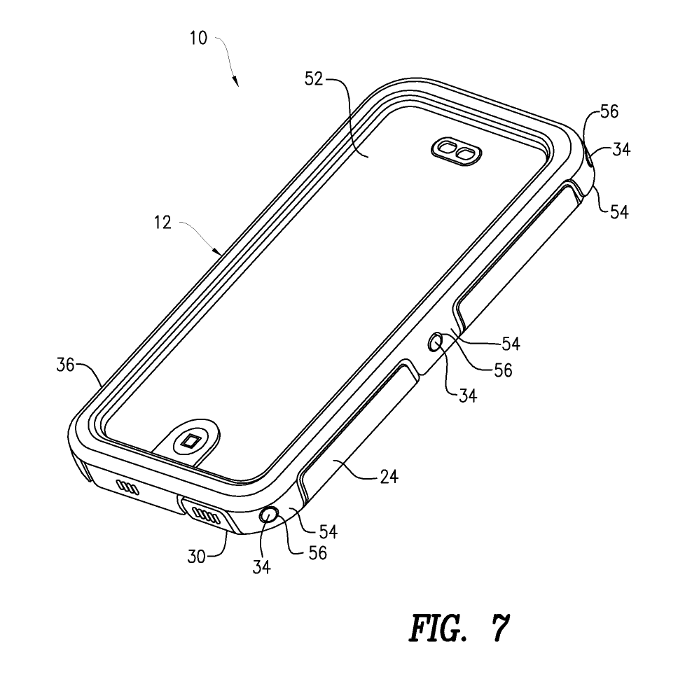

Referring now to FIG. 7, in another embodiment, the first mating element 34 and the second mating element 56 may be reversed, such that the first mating element 34 may be a protuberance or a nub extending a distance away from the first portion 14, and the second mating element 56 may be an aperture defined by the flaps 54 of the second portion 36. The reversal of the first mating element 34 and the second mating element 56 may provide for a substantially water resistant housing 12 when the first portion 14 is releaseably secured to the second portion 36. The first mating element 34 and the second mating element 56 may releaseably coupled to each other in the same manner as the embodiment shown in FIG. 6. Because, however, the first mating element 34 is a protuberance and disposed on the first portion 14 rather than an aperture, the first portion 14 is more water resistant than other embodiments in which the first mating element 34 is an aperture.

Continuing to refer to FIG. 7, the first portion 14 may include any number of first mating elements 34 extending away from an exterior surface of the side walls 16. For example, as shown in FIG. 7, three first mating elements 34 are disposed along a side wall 16 of the first portion 14. In particular, two first mating elements 24 are included at two of the corners 32 of the first portion 14 and a third first mating element 34 is included at substantially the midpoint of one of the side walls 16. An additional three first mating elements 34 are included on the on the opposite side wall 16 of the first portion 14 (not shown) for a total of six first mating elements 34 disposed on the side walls 16. Although not shown, any number of first mating elements 34 may be disposed symmetrically or asymmetrically around the side walls 16 or any portion of the first portion 14. A corresponding second mating element 56 may be included and positioned on the second portion 36 to mate with its corresponding first mating element 34 on the first portion 14. For example, if six first mating elements 34 are included on the first portion, six second mating elements 56 may be included on the second portion 36.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A mobile device case, comprising:
a first portion sized to at least partially retain a mobile device, the first portion having an exterior and including a plurality of corners at least one of the plurality of corners including at least one first mating element disposed on the exterior;
a second portion matable to the first portion, the second portion including at least one flap, each flap including a second mating element sized to releasably engage with a corresponding first mating element; and
each flap being disposed on the exterior portion of a corresponding corner when the first mating element is engaged with the second mating element;

2. The mobile device case of claim 1, wherein the first portion further includes a plurality of side wall portions, each of the plurality of side wall portions being composed of a first material having a first durometer and the at least one flap is composed of a second material having a second durometer lower that the first durometer.

3. The mobile device case of claim 2, wherein at least one of the plurality of the side wall portions include at least one of the first mating elements, and wherein the second portion includes a corresponding flap positioned on the first portion to mate with the first mating element included on the corresponding side wall portion.

4. The mobile device case of claim 3, wherein the second mating element includes a protuberance, and wherein the protuberance is composed of the second material and the protuberance extends at least partially through the first mating element.

5. The mobile device case of claim 3, wherein a portion of each of the plurality of side wall portions includes the first material having the second material molded to an exterior surface of the first material.

6. The mobile device case of claim 5, wherein at least one of the plurality of corners is disposed between two of the plurality of side wall portions having the second material.

7. The mobile device case of claim 1, wherein the second mating element is substantially commensurate in size with at least one of the plurality of corners.

8. The mobile device case of claim 1, wherein the at least one flap is deformable.

9. The mobile device case of claim 1, wherein the second portion includes a substantially planar screen protector; and wherein the at least one flap is substantially orthogonal to the screen protector when the first portion is mated to the second portion.

10. The mobile device case of claim 9, wherein the at least one flap is movable from a first position in which the at least one flap is substantially orthogonal to the screen protector to a second position in which the at least one flap is substantially parallel to the screen protector.

11. The mobile device case of claim 1, wherein when the first mating element mates with the second mating element, the at least one flap contours an exterior surface of the at least one of the plurality of corners.

12. A mobile device case, comprising:
a first portion sized to receive a mobile device;
a second portion releaseably securable to the first portion;
the first portion including a plurality of side wall portions composed of a substantially rigid material, the plurality of side wall portions including an exterior surface;
the second portion including at least one flap releaseably securable to at least one of the plurality of side wall portions; and
the at least one flap contouring the exterior surface of at least one of the plurality of side wall portions when the first portion is releasably secured to the second portion.

13. The mobile device case of claim 12, wherein the at least one flap includes a protuberance, and wherein at least one of the plurality of side wall portions includes an aperture, and where when the at least one flap is secured to at least one of the plurality of side portions, the protuberance is releasably securable within the aperture.

14. The mobile device case of claim 12, wherein the at least one flap is deformable.

15. The mobile device case of claim 12, wherein the second portion includes a substantially planar screen protector; and wherein the at least one flap is substantially orthogonal to the screen protector when the first portion is secured to the second portion.

16. The mobile device case of claim 15, wherein the at least one flap is movable from a first position in which the at least one flap is substantially orthogonal to the screen protector to a second position in which the at least one flap is substantially planar to the screen protector when the first portion is secured to the second portion.

17. The mobile device case of claim 12, wherein the first portion includes a corner disposed between two of the plurality of side wall portions and wherein at least one flap is positioned on the second portion to releasably secure the second portion to the corner.

18. The mobile device case of claim 12, wherein the second portion includes at least three flaps, wherein two of the at least two flaps releasably secures the second portion to two corresponding corners and wherein another of the at least three flaps releasably secures the second portion to one of the plurality of side wall portions.

19. The mobile device case of claim 17, further including a resilient material molded to the exterior surface of at least one of the plurality of side wall portions.

20. A mobile device case, comprising:
a first housing portion including at least one corner, the at least one corner defining an exterior surface and a protuberance extending away from the exterior surface;
a second housing portion releaseably engageable to the first housing portion, the second housing portion defining a substantially planar surface and including at least one flap, each flap having an aperture, the aperture being sized to mate with a corresponding protuberance;
the at least one flap is movable from a first position in which the at least one flap is substantially orthogonal to substantially planar surface to a second position in which the at least one flap is substantially planar to the substantially planar surface; and
the at least one flap is adjacent and contours the exterior surface of the corner and the second portion is releasably secured to the first portion.
